(19) United States
(12) Patent Application Publication
(10) Pub. No.: US 2026/0299421 A1
(43) Pub. Date: Oct. 1, 2026

(54) METHOD FOR FORMING AN UNDERLAYER, SEMICONDUCTOR STRUCTURE, AND REACTOR SYSTEM

(71) Applicant: ASM IP Holding B.V., Almere (NL)

(72) Inventor: Kishan Ashokbhai Patel, Leuven (BE)

(21) Appl. No.: 19/629,250

(22) Filed: Mar. 26, 2026

Related U.S. Application Data
(60) Provisional application No. 63/781,039, filed on Mar. 31, 2025.

(51) Int. Cl. G03F 7/11; C23C 16/44; C23C 16/455; G03F 7/16

(52) U.S. Cl. CPC G03F 7/11; C23C 16/4408; C23C 16/45536; C23C 16/45553; G03F 7/167

(57) ABSTRACT

A method for forming an underlayer for lithographic patterning is provided. The method includes providing a substrate into a reaction chamber and introducing a plasma into the reaction chamber. The method includes introducing a precursor gas into the reaction chamber, wherein the precursor gas comprises at least one carbon-carbon double bond.

### CROSS-REFERENCE TO RELATED APPLICATIONS

This application claims priority to U.S. Provisional Patent Application Ser. No. 63/781,039 filed Mar. 31, 2025 titled METHOD FOR FORMING AN UNDERLAYER, SEMICONDUCTOR STRUCTURE, AND REACTOR SYSTEM, the disclosure of which is hereby incorporated by reference in its entirety.

### FIELD

The present disclosure generally relates to methods of forming an underlayer for lithographic patterning. More particularly, examples of the disclosure relate to methods of forming an underlayer by a precursor gas containing a carbon-carbon double bond, to a semiconductor structure including the underlayer, and to a reactor system for performing the method.

### BACKGROUND

In the semiconductor industry, extreme ultraviolet (EUV) lithography has emerged as a critical technology for advanced device fabrication. As feature sizes continue to shrink, the need for precise patterning with high resolution and minimal defects has become increasingly important. One of the challenges in EUV lithography is optimizing the underlayer materials used in the patterning process. The underlayer plays a crucial role in improving lithographic performance by enhancing light absorption and reducing line-edge roughness (LER).

Carbon-based films have gained attention as potential EUV underlayer materials due to their favorable optical properties and compatibility with high-resolution imaging. However, achieving an optimal underlayer composition requires extensive material screening to balance multiple performance parameters, such as dose requirements, film stability, and etch selectivity.

Existing approaches to EUV underlayers often suffer from trade-offs between dose efficiency and process stability. Many conventional materials require high exposure doses to achieve adequate patterning fidelity, which can lead to higher costs and throughput limitations. Therefore, the continuous development and screening of novel chemical compositions is necessary to improve dose reduction and ensure stable processing conditions. The present disclosure addresses these challenges by introducing a newly screened chemical formulation designed to enhance EUV underlayer performance, thereby advancing semiconductor manufacturing efficiency.

### BRIEF SUMMARY

The present disclosure provides a method for forming an underlayer for lithographic patterning. The method includes providing a substrate into a reaction chamber. The method includes introducing a plasma into the reaction chamber. The method includes introducing a precursor gas into the reaction chamber, wherein the precursor gas includes at least one carbon-carbon double bond.

In some embodiments, the precursor gas includes a cyclic hydrocarbon structure with at least one carbon-carbon double bond in the ring structure. In some embodiments, the precursor gas further includes at least one branched substituent on the cyclic hydrocarbon structure. In some embodiments, the branched substituent includes at least one carbon-carbon double bond. In some embodiments, the precursor gas includes limonene and/or limonene derivatives.

In some embodiments, the limonene derivatives include limonene oxidation/epoxidation derivatives. In some embodiments, the limonene oxidation/epoxidation derivatives include one or more of: carvone (2-methyl-5-(prop-1-en-2-yl)cyclohex-2-en-1-one, C₁₀H₁₄O), carveol (2-methyl-5-(prop-1-en-2-yl)cyclohex-2-en-1-ol, C₁₀H₁₆O), limonene-1,2-oxide (1,2-epoxy-p-menth-8-ene, C₁₀H₁₆O), limonene dioxide (1,2; 8,9-diepoxy-p-menthane, C₁₀H₁₆O₂), perillyl alcohol (4-(prop-1-en-2-yl)cyclohex-1-en-1-methanol, C₁₀H₁₆O), perillic acid (4-(prop-1-en-2-yl)cyclohex-1-enecarboxylic acid, C₁₀H₁₄O₂), α-terpineol (p-menth-1-en-8-ol, C₁₀H₁₈O), limonene hydroperoxide (4-(prop-1-en-2-yl)cyclohex-1-en-1-yl hydroperoxide, C₁₀H₁₆O₂).

In some embodiments, the limonene derivatives include limonene addition and hydrogenation derivatives. In some embodiments, the limonene addition and hydrogenation derivatives include one or more of: dihydrolimonene (4-(propan-2-yl)-1-methylcyclohex-1-ene, C₁₀H₁₈), tetrahydrolimonene (p-menthane, C₁₀H₂₀), dihydrocarvone (2-methyl-5-(propan-2-yl)cyclohexan-1-one, C₁₀H₁₈O), dihydrocarveol (2-methyl-5-(propan-2-yl)cyclohexan-1-ol, C₁₀H₂₀O), limonene hydrochloride (4-(propan-2-yl)-1-methylcyclohex-1-yl chloride, C₁₀H₁₇Cl), limonene hydrobromide (4-(propan-2-yl)-1-methylcyclohex-1-yl bromide, C₁₀H₁₇Br), limonene maleic anhydride adduct (2,5-dioxabicyclo[2.2.2]octane-3,6-dione derivative, C₁₄H₂₀O₃), hydrogenated limonene polymer ([C₁₀H₁₆]ₙ).

In some embodiments, the limonene derivatives include limonene esterification or other functionalized derivatives. In some embodiments, the limonene esterification or other functionalized derivatives include one or more of: carvyl acetate (2-methyl-5-(prop-1-en-2-yl)cyclohex-2-en-1-yl acetate, C₁₂H₂₀O₂), carvyl propionate (2-methyl-5-(prop-1-en-2-yl)cyclohex-2-en-1-yl propanoate, C₁₃H₂₂O₂), dihydrocarvyl acetate (2-methyl-5-(propan-2-yl)cyclohexan-1-yl acetate, C₁₂H₂₂O₂), limonene acrylate (4-(prop-1-en-2-yl)-1-methylcyclohex-1-en-1-yl acrylate, C₁₃H₂₀O₂), limonene methacrylate (4-(prop-1-en-2-yl)-1-methylcyclohex-1-en-1-yl 2-methylprop-2-enoate, C₁₄H₂₂O₂), perillyl acetate (4-(prop-1-en-2-yl)cyclohex-1-en-1-yl acetate, C₁₂H₁₈O₂), epoxidized limonene acrylate (1,2-epoxy-4-(prop-1-en-2-yl)-1-methylcyclohex-1-yl acrylate, ~C₁₃H₂₀O₃), limonene carbonate (4-(prop-1-en-2-yl)-1-methyl-2-oxabicyclo[2.2.2]octan-3-one, C₁₀H₁₆O₃).

In some embodiments, the underlayer includes carbon-carbon double bonds. In some embodiments, the step of introducing the precursor gas into the reaction chamber is repeated several times. In some embodiments, the precursor gas is pulsing. In some embodiments, the plasma is selected from Ar plasma, He plasma, and N₂ plasma. In some embodiments, the method further including introducing a reactive gas into the reaction chamber. In some embodiments, the reactive gas is selected from H₂, O₂ CO₂, and NH₃, and the reactive gas is continuous. In some embodiments, the method further including purging the reaction chamber.

In some embodiments, the limonene derivatives include monoterpenes or other functionalized derivatives. In some embodiments, the monoterpenes derivatives include one or more of: pinene (C₁₀H₁₆), carene (C₁₀H₁₆), camphene (C₁₀H₁₆), terpinene (C₁₀H₁₆), phellandrene (C₁₀H₁₆), sabinene (C₁₀H₁₆), terpinolene (C₁₀H₁₆)

### BRIEF DESCRIPTION OF THE DRAWINGS

The present invention can be more fully understood by reading the subsequent detailed description and examples with references made to the accompanying drawings, wherein:

FIG. 1 is a schematic view of a method for forming an underlayer over a substrate according to some embodiments of the present disclosure;

FIG. 2 is a timing sequence suitable for use with the method 100 according to some embodiments of the present disclosure;

FIG. 3 is a schematic view of a method for forming an underlayer over a substrate according to some embodiments of the present disclosure;

FIG. 4 is a timing sequence suitable for use with the method 300 according to some embodiments of the present disclosure;

FIG. 5 is a semiconductor structure according to some embodiments of the present disclosure;

FIG. 6 is a reactor system according to some embodiments of the present disclosure;

FIG. 7 illustrates properties of the underlayers form by methods according to some embodiments of the present disclosure; and

FIG. 8 illustrates properties of the underlayers form by methods according to some embodiments of the present disclosure.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide. In some embodiments, the substrate can have an OH termination. The OH termination can occur natively, e.g., it can occur through atmospheric oxidation, or the OH termination can be provided intentionally, e.g., by subjecting the substrate to a plasma treatment.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Exposure of a substrate to precursor can result in one or more of physisorption and chemisorption of at least one of precursor and precursor fragments on the substrate. Ones from the plurality of reactant pulses can result in one or more of physisorption and chemisorption of at least one of reactant and reactant fragments on the substrate.

It will be understood that although the terms “first,” “second,” and the like may be used herein to describe various members, regions, layers, and/or portions, these members, regions, layers, and/or portions should not be limited by these terms. The terms do not refer to a specific order, a vertical relationship, or a preference, and are only used to distinguish one member, region, or portion from another member, region, or portion. Accordingly, a first member, region, or portion that will be described below may refer to a second member, region, or portion without departing from the teaching of the present disclosure.

As used herein substantially or about the same means ±5%, ±2%, ±1%, or ±0.5% of another value or shape—e.g., one or more cross-sectional dimensions of the shape. The percentages can be absolute or relative.

In the drawings, variations from the shapes of the illustrations as a result, for example, of manufacturing techniques and/or tolerances, are to be expected. Thus, embodiments should not be construed as limited to the particular shapes of regions illustrated herein but may be to include deviations in shapes that result, for example, from manufacturing. Further, the drawing figures may be used to illustrate various features, which may not be drawn to scale.

Expressions, such as “at least one of,” when preceding a list of elements, modify the entire list of elements and do not modify the individual elements of the list.

As used herein, “atomic layer deposition”, abbreviated as “ALD”, refers to a method of depositing a film on a substrate by sequentially exposing its surface to alternate gas-phase reactants. In contrast to chemical vapor deposition, the different reactants are not simultaneously present in the reactor, but rather they are introduced as a series of sequential, non-overlapping pulses. In each of these pulses, the reactant reacts with the surface in a self-limiting way or a substantially self-limiting way. Further, ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants. Plasma enhanced atomic-layer deposition (PEALD) refers to an ALD process, in which a plasma is applied during one or more of the ALD steps or substeps.

As used herein, “chemical vapor deposition”, abbreviated as “CVD”, refers to a method of depositing a film on a substrate by exposing its surface to one or more gaseous reactants, which react and/or decompose on the substrate surface to produce a desired film. Typically, CVD is performed by co-introducing the reactants into a reactor. Plasma enhanced chemical vapor deposition (PECVD) refers to a CVD process, in which a plasma is applied during one or more of the CVD steps or substeps.

As used herein, “chemisorption” refers to an adsorption process, caused by a reaction on an exposed surface, which creates, for example, a covalent or ionic bond between the surface and the adsorbate.

As used herein, a “film” refers to a continuous, substantially continuous, or non-continuous material that extends in a direction perpendicular to a thickness direction to cover at least a portion of a surface. A film can include two-dimensional materials, three-dimensional materials, nanoparticles or even partial or full molecular layers or partial or full atomic layers or clusters of atoms and/or molecules. A film may be built up from one or more non-discernable layers (e.g., monolayers or sub-monolayers) to produce a uniform or a substantially uniform material, wherein the number of layers influences the thickness of the material.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein, a “plasma” refers to an ionized gas comprising roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their pro-duction of excited and reactive species and, as a result, they can provide very different fluxes of the various species.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, “self-limiting” refers to a process that proceeds by a finite course and that terminates once the finite course is complete. For example, a self-limiting surface reaction terminates when the surface becomes saturated and all of the available and/or accessible surface reactive sites are depleted. At maximum one monolayer may be formed on the surface.

As used herein, a “substituent” refers to an atom or a group of atoms that re-places one or more atoms (such as a hydrogen atom) or groups of atoms in a parent compound, thereby resulting in a new compound. The substituent is substituted for the original atom or a group of atoms in the parent molecule. For simplicity, a substituent may be indicated in a chemical formula as an “R” group and each “R” group in a compound may be independently selected unless otherwise specifically indicated that this is not the case. Examples of substituent groups include, but are not limited to: a hydrogen atom (H); an “alkyl group”, such as a saturated linear or branched C₁ to C₁₀ hydrocarbons, preferably C₁ to C₆ hydrocarbons (e.g., methyl, ethyl, propyl, iso-propyl, butyl, i-butyl, s-butyl, t-butyl, pentyl, 3-pentyl, neo-pentyl, and hexyl); a “cycloalkyl group”, such as C₃ to C₆ cyclic hydrocarbons (e.g., cyclopropyl, cyclobutyl, cyclopentyl, and cyclohexyl); an “alkenyl group”, such as C₂ to C₆ linear or branched unsaturated hydrocarbons (e.g., vinyl, allyl, propenyl, butenyl, pen-tenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl, and methyl, dimethyl, or ethyl cyclopentadienyl groups; a hydroxy group (OH); an “alkoxy group”, such as a linear or branched C₁ to C₁₀ alkoxy group, typically a C₁ to C₄ alkoxy group (e.g., methoxy, ethoxy, n-propoxy, i-propoxy, butoxy, iso-butoxy, sec-butoxy, and tert-butoxy); a hydroxyalkyl group such as a linear or branched a C₁ to C₁₀ hydroxyalkyl, typically a linear or branched C₁ to C₄ hydroxyalkyl (e.g., hydroxymethyl, hydroxyethyl, hydroxypropyl, hydroxybutyl, hydroxypentyl, and hydroxyhexyl); an “alkoxycarbonyl group”, such as a linear or branched C₁ to C₆ carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group”, such as a linear or branched C₁ to C₆ thiols (e.g., thiolmethyl, thiolethyl, thiolpropyl, thiolbutyl, thiolpentyl, and thiolhexyl); a halide (X), such as fluoride (F), chloride (Cl), bromide (Br), and iodide (I); and an “haloalkyl group”, such as a linear or branched C₁ to C₆ alkylhalides having one or more halogen atoms (e.g., iodomethyl, bromomethyl, chloromethyl, fluoromethyl, trifluoromethyl, 2-chloroethyl, 2-fluoroethyl, 2,2,2-trifluoroethyl, and pentafluoroethyl). A substituent group may, in and of itself, be substituted. For example, a hydroxyalkyl group is a substituted alkyl group, where a H atom on the alkyl group is replaced with an OH group.

Articles “a” or “an” refer to a species or a genus including multiple species, depending on the context. As such, the terms “a/an”, “one or more” and “at least one” can be used interchangeably herein. It is also to be noted that the terms “comprising”, “including”, and “having” can be used interchangeably.

The term “about” generally refers to a range of numbers that is considered equivalent to the recited value (e.g., having the same function or result). In some instances, the term about may include numbers that are rounded to the nearest significant figure.

The term “essentially” as applied to a composition, a method, or a system generally means that the additional components do not substantially modify the properties and/or function of the composition, the method, or the system.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%. “At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

The present disclosure generally relates to methods of forming an underlayer over a substrate using CVD (such as PECVD, for example), or ALD (such as PEALD, for example), a semiconductor structure with the underlayer and a reactor system for performing the method, and in particular to the use of a precursor gas with at least one carbon-carbon double bond to form an underlayer with carbon-carbon double bonds to offer dose reduction for EUV lithography. Various aspects of the methods and systems and the benefits derived therefrom will now be described.

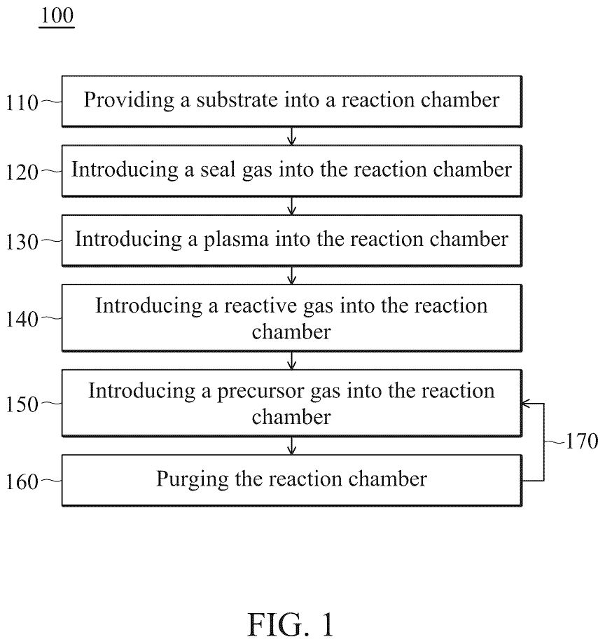

Turning now to figures, FIG. 1 is a schematic view of a method 100 for forming an underlayer over a substrate according to some embodiments of the present disclosure. Step 110 comprises, providing a substrate into a reaction chamber. Next, step 120 involves introducing a seal gas into the reaction chamber. Next, step 130 involves introducing a plasma into the reaction chamber. Next, step 140 involves introducing a reactive gas into the reaction chamber. Next, step 150 involves introducing a precursor gas into the reaction chamber. Next, step 150 involves purging the reaction chamber. The method 100 also includes a cycle 170. The cycle 170 includes the step 150 and the step 160. The cycle 170 is repeated one or more times (e.g., several) until the desired underlayer is formed.

In some embodiments, the precursor gas includes a cyclic hydrocarbon structure with at least one carbon-carbon double bond in the ring structure.

In some embodiments, the precursor gas includes a cyclic hydrocarbon structure with at least one branched substituent on the cyclic hydrocarbon structure with at least one carbon-carbon double bond in the ring structure.

In some embodiments, the precursor gas includes a cyclic hydrocarbon structure with at least one branched substituent on the cyclic hydrocarbon structure, and the branched substituent comprises at least one carbon-carbon double bond.

In some embodiments, the precursor gas includes a cyclic hydrocarbon structure with at least one branched substituent on the cyclic hydrocarbon structure with at least one carbon-carbon double bond in the ring structure, and the branched substituent comprises at least one carbon-carbon double bond.

In some embodiments, the precursor gas includes limonene and/or limonene derivatives.

In some embodiments, the limonene derivatives include monoterpenes or other functionalized derivatives.

In some embodiments, the monoterpenes derivatives include one or more of: pinene (C₁₀H₁₆), carene (C₁₀H₁₆), camphene (C₁₀H₁₆), terpinene (C₁₀H₁₆), phellandrene (C₁₀H₁₆), sabinene (C₁₀H₁₆), terpinolene (C₁₀H₁₆).

In some embodiments, the limonene derivatives include limonene oxidation/epoxidation derivatives.

In some embodiments, the limonene oxidation/epoxidation derivatives include one or more of: carvone (2-methyl-5-(prop-1-en-2-yl)cyclohex-2-en-1-one, C₁₀H₁₄O), carveol (2-methyl-5-(prop-1-en-2-yl)cyclohex-2-en-1-ol, C₁₀H₁₆O), limonene-1,2-oxide (1,2-epoxy-p-menth-8-ene, C₁₀H₁₆O), limonene dioxide (1,2; 8,9-diepoxy-p-menthane, C₁₀H₁₆O₂), perillyl alcohol (4-(prop-1-en-2-yl)cyclohex-1-en-1-methanol, C₁₀H₁₆O), perillic acid (4-(prop-1-en-2-yl)cyclohex-1-enecarboxylic acid, C₁₀H₁₄O₂), α-terpineol (p-menth-1-en-8-ol, C₁₀H₁₈O), limonene hydroperoxide (4-(prop-1-en-2-yl)cyclohex-1-en-1-yl hydroperoxide, C₁₀H₁₆O₂).

In some embodiments, the limonene derivatives include limonene addition and hydrogenation derivatives.

In some embodiments, the limonene addition and hydrogenation derivatives include one or more of: dihydrolimonene (4-(propan-2-yl)-1-methylcyclohex-1-ene, C₁₀H₁₈), tetrahydrolimonene (p-menthane, C₁₀H₂₀), dihydrocarvone (2-methyl-5-(propan-2-yl)cyclohexan-1-one, C₁₀H₁₈O), dihydrocarveol (2-methyl-5-(propan-2-yl)cyclohexan-1-ol, C₁₀H₂₀O), limonene hydrochloride (4-(propan-2-yl)-1-methylcyclohex-1-yl chloride, C₁₀H₁₇Cl), limonene hydrobromide (4-(propan-2-yl)-1-methylcyclohex-1-yl bromide, C₁₀H₁₇Br), limonene maleic anhydride adduct (2,5-dioxabicyclo[2.2.2]octane-3,6-dione derivative, C₁₄H₂₀O₃), hydrogenated limonene polymer ([C₁₀H₁₆]ₙ).

In some embodiments, the limonene derivatives include limonene esterification or other functionalized derivatives.

In some embodiments, the limonene esterification or other functionalized derivatives include one or more of: carvyl acetate (2-methyl-5-(prop-1-en-2-yl)cyclohex-2-en-1-yl acetate, C₁₂H₂₀O₂), carvyl propionate (2-methyl-5-(prop-1-en-2-yl)cyclohex-2-en-1-yl propanoate, C₁₃H₂₂O₂), dihydrocarvyl acetate (2-methyl-5-(propan-2-yl)cyclohexan-1-yl acetate, C₁₂H₂₂O₂), limonene acrylate (4-(prop-1-en-2-yl)-1-methylcyclohex-1-en-1-yl acrylate, C₁₃H₂₀O₂), limonene methacrylate (4-(prop-1-en-2-yl)-1-methylcyclohex-1-en-1-yl 2-methylprop-2-enoate, C₁₄H₂₂O₂), perillyl acetate (4-(prop-1-en-2-yl)cyclohex-1-en-1-yl acetate, C₁₂H₁₈O₂), epoxidized limonene acrylate (1,2-epoxy-4-(prop-1-en-2-yl)-1-methylcyclohex-1-yl acrylate, ~C₁₃H₂₀O₃), limonene carbonate (4-(prop-1-en-2-yl)-1-methyl-2-oxabicyclo[2.2.2]octan-3-one, C₁₀H₁₆O₃).

In some embodiments, the precursor gas is pulsed.

In some embodiments, the plasma is continuous.

In some embodiments, the plasma is selected from a Ar plasma, a He plasma, a N₂ plasma, or mixtures thereof.

In some embodiments, the reactive gas is selected from H₂, O₂, CO₂, NH₃, and mixtures thereof.

In some embodiments, the reactive gas is supplied in a continuous manner.

In some embodiments, the underlayer formed using the method 100 includes carbon-carbon double bonds.

The sequence of the steps in the method 100 is only an example; the sequence can be varied in other embodiments. For example, in some embodiments, the step 130 and the step 140 are performed at the same time. For example, in some embodiments, the step 120, the step 130 and the step 140 are performed at the same time. For example, in some embodiments, the step 140 is performed prior to the step 130.

In some embodiments, method 100 can comprise other additional steps. For example, in some embodiments, there is an additional step for providing a second reactive gas. For example, in some embodiments, there is an additional step for providing a second plasma. For example, in some embodiments, there is an additional step for providing a second precursor gas. For example, in some embodiments, there is an additional step for providing a second purge gas.

In some embodiments, the additional precursor gas includes an aromatic compound.

In some embodiments, the additional precursor gas is selected from the list consisting of benzene, alkylbenzene, toluene, ethylbenzene, xylene, durene, aniline, phenol, benzoic acid, biphenyl, mesitylene, styrene, toluidine, toluic acid, cresol, and, naphthalene. In some embodiments, the additional precursor gas is selected from the list consisting of o-xylene, m-xylene, p-xylene. Same applies for toluic acid and cresol.

In some embodiments, the additional precursor gas includes an alkylbenzene. In some embodiments, the alkylbenzene comprises trimethylbenzene. In some embodiments, the alkylbenzene comprises 1,2,4-trimethylbenzene.

In some embodiments, the additional precursor gas includes a hydrocarbon. In some embodiments, the additional precursor gas includes an alkane. In some embodiments, the additional precursor gas includes a linear alkane. In some embodiments, the additional precursor gas includes a branched alkane. In some embodiments, the additional precursor gas includes one or more of methane, ethane, propane, butane, pentane, hexane, heptane, octane, nonane, and decane.

In some embodiments, the additional precursor gas includes an aliphatic hydrocarbon.

In some embodiments, the additional precursor gas is selected from an alkylbenzene such as 1,2,4-trimethylbenze and an organic acid anhydride such as 2-hydroxy-2-methylpropiophenone.

In some embodiments, the additional precursor gas includes a double carboxylic acid anhydride. In some embodiments, the double carboxylic acid anhydride comprises pyromellitic dianhydride. In some embodiments, the additional precursor gas includes an anhydride, such as furan-2,5-dione (maleic acid anhydride). The anhydride can be a dianhydride, e.g., pyromellitic dianhydride (PMDA). In some embodiments, the additional precursor gas can be any other monomer with two reactive groups which will react with the reactant.

In some embodiments, the additional precursor gas is selected from Ethylenediaminetetraacetic Dianhydride, 1,2,4,5-Cyclohexanetetracarboxylic Dianhydride, 1,2,3,4-butanetetracarboxylic dianhydride, Bicyclo[2.2.2]oct-7-ene-2,3,5,6-tetracarboxylic Dianhydride, 4,4′-Biphthalic Anhydride, 1,2,3,4-Cyclobutanetetracarboxylic Dianhydride, and 3-(Carboxymethyl)-1,2,4-cyclopentanetricarboxylic Acid 1,4:2,3-dianhydride.

In some embodiments, the additional precursor gas includes pyromellitic dianhydride (PMDA).

In some embodiments, the reactive gas and/or the additional reactive gas includes a diamine. In some embodiments, the diamine is selected from the list consisting of 1,6-diaminohexane, 1,4-diaminocyclohexane, and 1,4-diaminobenzene.

In some embodiments, the diamine is selected from the list consisting of 1,2-diaminoethane, 1,3-diaminopropane, 1,4-diaminobutane, 1,5-Diaminopentane, 1,7-di-aminoheptane, 1,8-diaminooctane, 1,4-Bis(aminomethyl)cyclohexane, 2-Methyl-1,5-pentanediamine, 2,2-Dimethyl-1,3-propanediamine, 1,3-Propanediamine, Propylenediamine, 2-Methyl-1,3-propanediamine, 2-Methyl-1,5-pentanediamine, 1,3-Pentanediamine, and 1,2-Pentanediamine.

In some embodiments, the reactive gas and/or the additional reactive gas includes, for example, 1,6-diaminohexane, 1,3-diaminopentane, triamine, such as tris(2-aminoethyl)amine, or a cyclic compound comprising at least two primary amine groups, such as 1,4-diaminocyclohexane or p-phenylenediamine. In some embodiments, the substrate is contacted with the reactive gas and/or the additional reactive gas before it is contacted with the precursor gas. In some embodiments, the substrate is contacted with the precursor gas before it is contacted with the reactive gas and/or the additional reactive gas.

In some embodiments, the plasma employs a plasma gas that comprises a noble gas.

In some embodiments, the noble gas comprises argon.

In some embodiments, the plasma gas further comprises hydrogen.

In some embodiments, the plasma gas comprises, consists essentially of, or consists of a noble gas such as argon. In some embodiments, the plasma gas comprises, consists essentially of, or consists of a noble gas and hydrogen. In some embodiments, the plasma gas comprises, consists essentially of, or consists of argon and hydrogen.

In some embodiments, the plasma gas comprises, consists essentially of, or consists of Ar. In some embodiments, the plasma gas comprises, consists essentially of, or consists of He. In some embodiments, the plasma gas comprises, consists essentially of, or consists of Ar and He. In some embodiments, the plasma gas comprises, consists essentially of, or consists of Ar and H₂. In some embodiments, the plasma gas comprises, consists essentially of, or consists of Ar and N₂. In some embodiments, the plasma gas comprises, consists essentially of, or consists of Ar, H₂, and N₂. In some embodiments, the plasma gas comprises, consists essentially of, or consists of He and H₂. In some embodiments, the plasma gas comprises, consists essentially of, or consists of He, H₂, and N₂. In some embodiments, the plasma gas comprises, consists essentially of, or consists of Ar, H₂, and formic acid. In some embodiments, the plasma gas comprises, consists essentially of, or consists of Ar, N₂, and formic acid.

In some embodiments, the plasma can be a remote or an indirect plasma, and the plasma-generated species to which the substrate is exposed can substantially consist of radicals. Such approaches can be referred to as radical-enhanced atomic layer deposition (RE-ALD). Any plasma gas as disclosed herein can be employed in a remote or indirect plasma configuration. In some embodiments, the plasma gas comprises a mixture of argon and H₂. When a remote or indirect plasma is employed, the substrate can be separated from the plasma by means of a mesh, a perforated plate, or the like.

In some embodiments, the plasma gas comprises a noble gas. Additionally, or alternatively, the noble gas can comprise one or more of an oxygen reactant, a nitrogen reactant, a boron reactant, and a carbon reactant. Suitable oxygen reactants can be selected from O₂, O₃, H₂O, H₂O₂, N₂O, NO, NO₂, and NO₃. Suitable nitrogen reactants can be selected from N₂, NH₃, and N₂H₂. Suitable carbon reactants can comprise hydrocarbons such as alkanes such as CH₄, formic acid, isopropanol. Suitable boron reactants can comprise borohydrides such as B₂H₆, B₃H₆N₃, Suitable sulfur reactants can comprise hydrogen sulfide (H₂S), Carbon disulfide (CS₂), Sulfur(S). Suitable phosphorus reactants can comprise Phosphine (PH₃), white phosphorus.

In some embodiments, the plasma gas comprises a noble gas and hydrogen. For example, the plasma gas can comprise Ar and H₂.

In some embodiments, the plasma gas comprises a noble gas and a silicon (Si) precursor and/or a carbon (C) precursor. In some embodiments, the precursor comprises Si and C. In some embodiments, the precursor comprises a Si—C bond. In some embodiments, the precursor comprises an alkyl, alkenyl, alkynyl, or aryl group attached to silicon. In some embodiments, the precursor comprises an alkylamino group attached to Si. In some embodiments, the alkylamino is selected from —NMe₂, —NEt₂, —NEtMe, —NHtBu, —N(iPr)₂, —N(sBu)₂, —N(SiMe₃)₂, —N(SiEt₃)₂. In some embodiments, the precursor comprises an alkoxy group attached to Si. In some embodiments, the alkoxy group is selected from —OMe, —OEt, —OiPr, —OtBu, —OsBu, —OtPn, —OSiMe₃, or —OSiEt₃.

For example, the oxygen plasma can comprise an O₂ plasma, i.e., a plasma that employs a plasma gas that comprises O₂. For example, the oxygen plasma can comprise a H₂O plasma, i.e., a plasma that employs a plasma gas that comprises H₂O, e.g., a plasma gas that comprises, consists essentially of, or consists of Ar and H₂O. In some embodiments, the plasma gas comprises O₂ and Ar. In some embodiments, the plasma gas comprises, consists essentially of, or consists of O2 and Ar. Advantageously, it was found that treating an underlayer according to an embodiment of the present disclosure for 2 seconds with an O₂ plasma can result in improved adhesion of metalorganic resist, in particular, features having a smaller critical dimension could be printed without defects. Without the subject matter of the present disclosure being bound by any particular theory or mode of operation, it is believed that this may be related to the underlayer having an increased polar component of its surface energy. It is assumed that these plasmas reduce H terminated carbon atoms at the surface and increase O on the surface. In some embodiments, these specific plasmas employ a plasma power less than 500W for a 300 mm wafer, and may last up to 60 seconds, e.g., for 2-5 seconds, to avoid damage to the surface and from modifying deeper layers of the underlayer. Other conditions may be modified to tune the stability of the plasma and the degree of change to the underlayer. A small penalty to the dose-reduction due to the surface modification is sometimes seen, but the dose reduction is still high and is considered an acceptable trade-off for the adhesion improvement.

In some embodiments, some of the steps can be omitted. For example, in some embodiments, the step 120 is omitted. For example, in some embodiments, the step 130 is omitted. For example, in some embodiments, the step 140 is omitted. For example, in some embodiments, the step 160 is omitted.

Advantageously, underlayers formed using embodiments of methods according to the present disclosure exhibit dose reduction. Advantageously, underlayers formed using embodiments of methods according to the present disclosure exhibit low line edge roughness (LER).

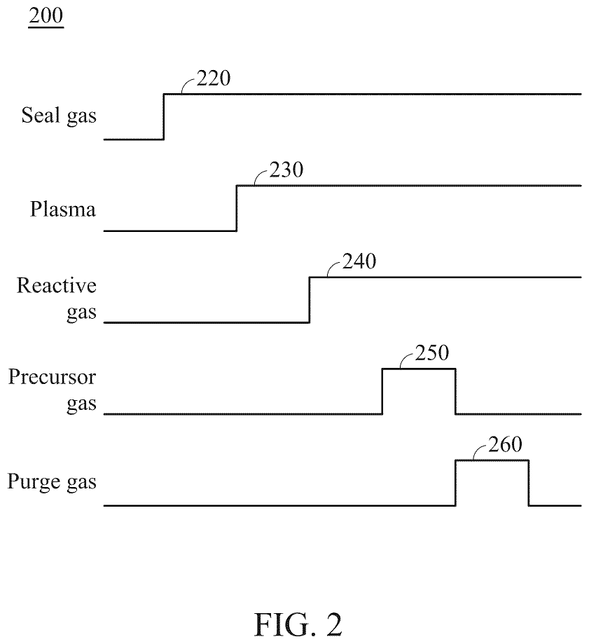

FIG. 2 illustrates a timing sequence 200 suitable for use with the method 100 according to some embodiments of the present disclosure. The timing sequence 200 includes a seal gas period 220, a plasma period 230, a reactive gas period 240, a precursor gas period 250, and a purge gas period 260.

In the embodiment of FIG. 2, the seal gas is provided in the seal gas period 220 and the seal gas period 220 starts before the plasma period 230, and the seal gas period 220 continues for the whole sequence. The plasma is provided in the plasma period 230, and the plasma period 230 starts before the reactive gas period 240. The reactive gas is provided in the reactive gas period 240, and the reactive gas period 240 starts before the precursor gas period 250. The precursor gas is pulsed in the precursor gas period 250, and the precursor gas period 250 is overlapped with the plasma period 230 and the reactive gas period 240. The purge gas is pulsed in the purge gas period 260 to purge the reaction chamber.

The composition and behavior of the plasma, the reactive gas, the precursor gas, the underlayer in the timing sequence 200 are similar to the plasma, the reactive gas, the precursor gas, the underlayer of the method 100.

As used herein, pulse period means a period in which a gas (e.g., precursor, reactant, inert gas, and/or carrier gas) is flowed to a reaction chamber and/or a period in which power is applied (e.g., power to produce a plasma). A height and/or width of the illustrated pulse period is not necessarily indicative of a particular amount or duration of a pulse.

A purge can comprise exposing the substrate to an inert gas such as a noble gas such as argon.

In some embodiments, the precursor gas pulse comprises a plurality of micro precursor gas pulses. In some embodiments, the reactive gas pulse comprises a plurality of micro reactive gas pulses. Precursor gas and reactive gas can be commonly referred to as reactive species, and corresponding pulses can be referred to as reactive pulses.

The timing sequence 200 is only an example; the duration and starting point of each period can be varied in other embodiments. For example, in some embodiments, the plasma period 230 and the reactive gas period 240 are started at the same time. For example, in some embodiments, the seal gas period 220, the plasma period 230 and the reactive gas period 240 are started at the same time. For example, in some embodiments, the reactive gas period 240 starts before the plasma period 230.

In some embodiments, other period is provided. For example, in some embodiments, there are two or more reactive gas periods. For example, in some embodiments, there are two or more plasma periods. For example, in some embodiments, there are two or more precursor gas periods. For example, in some embodiments, there are two or more purge gas periods.

In some embodiments, some of the periods are omitted. For example, in some embodiments, the seal gas period is omitted. For example, in some embodiments, the plasma period is omitted. For example, in some embodiments, the reactive gas period is omitted. For example, in some embodiments, the purge gas period is omitted.

Advantageously, underlayers formed using timing sequences of methods according to the present disclosure exhibit dose reduction. Advantageously, underlayers formed using embodiments of methods according to the present disclosure exhibit low line edge roughness (LER).

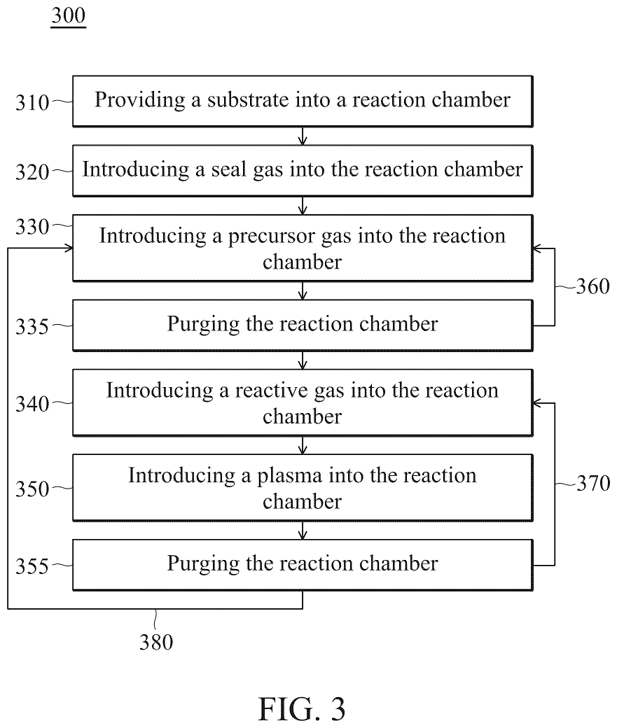

FIG. 3 illustrates a schematic view of a method 300 for forming an underlayer over a substrate according to some embodiments of the present disclosure. Step 310 comprises, providing a substrate into a reaction chamber. Next, step 320 involves introducing a seal gas into the reaction chamber. Next, step 330 involves introducing a precursor gas into the reaction chamber. Next, step 335 involves purging the reaction chamber. Next, step 1340 involves introducing a reactive gas into the reaction chamber. Next, step 350 involves introducing a plasma into the reaction chamber. Next, step 355 involves purging the reaction chamber.

The method 300 also includes a sub-cycle 360 and a sub-cycle 370. The sub-cycle 360 includes the step 330 and the step 335, and the sub-cycle 360 is repeated one or more times (e.g., several times) until enough precursor gas is adsorbed onto the substrate. The sub-cycle 370 includes the step 340, the step 350 and the step 355, and the sub-cycle 370 is repeated one or more times (e.g., several times) until the gases in the reaction chamber is well reacted. The sub-cycle 360 and the sub-cycle 370 together form a cycle 380, and the cycle 380 is repeated one or more times until the desired underlayer is formed.

The composition and behavior of the plasma, the reactive gas, the precursor gas, the underlayer of the method 300 are similar to the plasma, the reactive gas, the precursor gas, the underlayer of the method 100.

The sequence of the steps in the method 300 is only an example; the sequence can be varied in other embodiments. For example, in some embodiments, the step 340 and the step 350 are performed at the same time. For example, in some embodiments, the step 350 is performed prior to the step 340.

In some embodiments, other additional steps can be provided. For example, in some embodiments, there is an additional step for providing a second precursor gas. For example, in some embodiments, there is an additional step for providing a second reactive gas. For example, in some embodiments, there is an additional step for providing a second plasma. For example, in some embodiments, there is an additional step for providing a third purge gas.

In some embodiments, some of the periods are omitted. For example, in some embodiments, the step 320 is omitted. For example, in some embodiments, the step 130 is omitted. For example, in some embodiments, the step 350 is omitted. For example, in some embodiments, the step 355 is omitted.

Advantageously, underlayers formed using embodiments of methods according to the present disclosure exhibit dose reduction. Advantageously, underlayers formed using embodiments of methods according to the present disclosure exhibit low line edge roughness (LER).

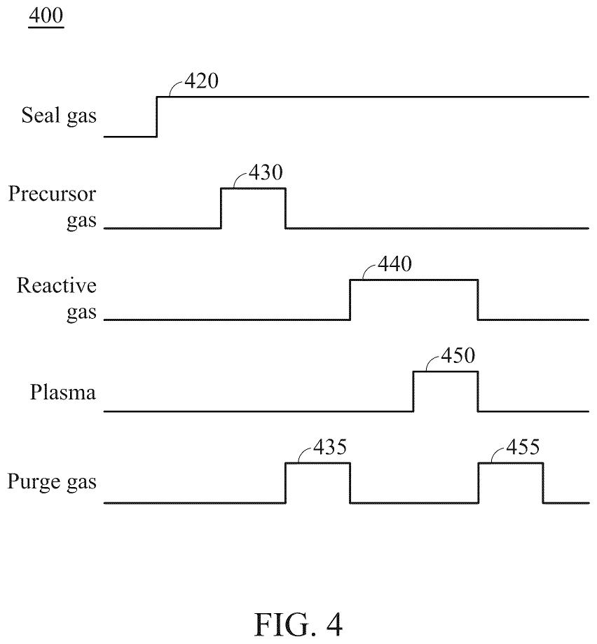

FIG. 4 illustrates is a timing sequence 400 suitable for use with the method 30 according to some embodiments of the present disclosure. The timing sequence 400 includes a seal gas period 420, a precursor gas period 430, a first purge gas period 435, a reactive gas period 440, a plasma period 450, and a second purge gas period 455.

In the embodiments of FIG. 4, the seal gas is provided in the seal gas period 420, and the seal gas period 420, and the seal gas period 220 continues for the whole sequence. The precursor gas is pulsed in the precursor gas period 430, and the precursor gas period 430 starts before the reactive gas period 440. The first purge gas is pulsed in the first purge gas period 435, and the first purge gas period 435 starts after the precursor gas period 430. The reactive gas is pulsed in the reactive gas period 440, and the reactive gas period 440 starts before the plasma period 450. The plasma is pulsed in the plasma period 450, and the plasma period 450 is overlapped with the reactive gas period 440. The second purge gas is pulsed in the second purge gas period 455, and the second purge gas period 455 starts after the plasma period 450.

As used herein, pulse period means a period in which a gas (e.g., precursor, reactant, inert gas, and/or carrier gas) is flowed to a reaction chamber and/or a period in which power is applied (e.g., power to produce a plasma). A height and/or width of the illustrated pulse period is not necessarily indicative of a particular amount or duration of a pulse.

The composition and behavior of the plasma, the reactive gas, the precursor gas, the underlayer of the timing sequence 400 are similar to the plasma, the reactive gas, the precursor gas, the underlayer of the method 100.

The timing sequence 400 is only an example; the duration and starting point of each period can be varied in other embodiments. For example, in some embodiments, the reactive gas period 440 and the plasma period 450 are started at the same time. For example, in some embodiments, the plasma period 450 starts before the reactive gas period 440.

In some embodiments, other period is provided. For example, in some embodiments, there are two or more precursor gas periods. For example, in some embodiments, there are two or more reactive gas periods. For example, in some embodiments, there are two or more plasma periods. For example, in some embodiments, there are additional purge gas periods.

In some embodiments, some of the periods are omitted. For example, in some embodiments, the seal gas period is omitted. For example, in some embodiments, the plasma period is omitted. For example, in some embodiments, some of the purge gas period is omitted.

Advantageously, underlayers formed using timing sequences of methods according to the present disclosure exhibit dose reduction. Advantageously, underlayers formed using embodiments of methods according to the present disclosure exhibit low line edge roughness (LER).

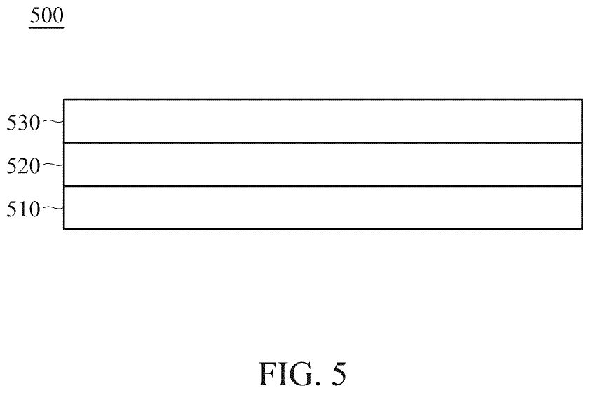

FIG. 5 illustrates a semiconductor structure 500 according to some embodiments of the present disclosure. The semiconductor structure 500 includes a substrate 510, an underlayer 520 and a photoresist 530. The underlayer 520 is formed overlying the substrate 510, and the photoresist 530 is formed overlying the substrate 510. The underlayer 520 includes carbon-carbon double bonds, and the underlayer 520 can be formed using method 100 or method 300. The photoresist 530 may be a EUV resist, such as a metalorganic resist, or a metal oxide resist (MOR). The underlayer 520 of the semiconductor structure 500 is similar to the underlayer of method 100 and method 300.

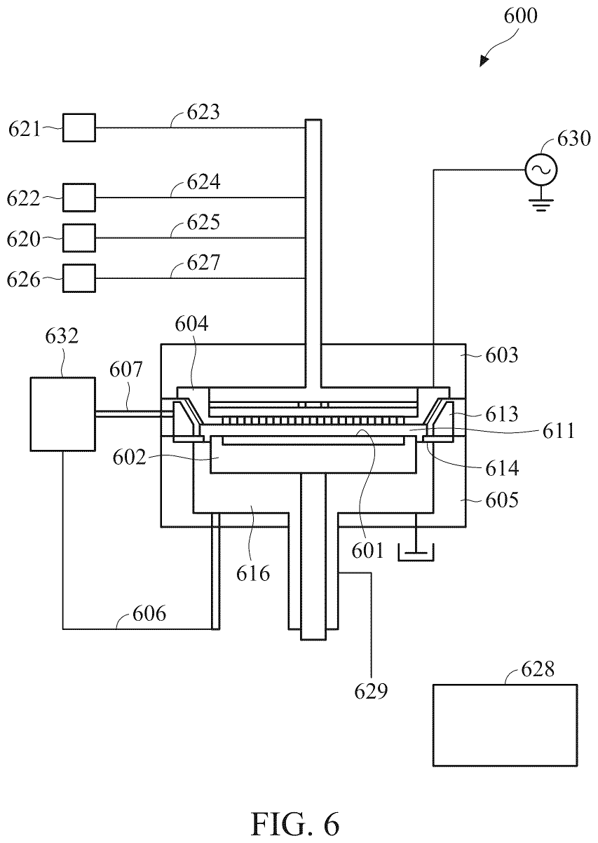

Turning now to FIG. 6, a reactor system 600 is illustrated in accordance with exemplary embodiments of the disclosure. Reactor system 600 can be used to perform one or more steps or substeps as described herein and/or to form one or more structures or portions thereof as described herein.

Reactor system 600 includes a pair of electrically conductive flat-plate electrodes 604, 602 in parallel and facing each other in the interior 611 (reaction zone) of a reaction chamber 603. Although illustrated with one reaction chamber, system 600 can include two or more reaction chambers. A plasma can be excited within reaction chamber 603 by applying, for example, HRF power (e.g., 100 kHz, 13.56 MHz, 27 MHz, 2.45 GHz, or any values therebetween) from plasma power source 630 to one electrode (e.g., upper electrode 604) and electrically grounding the other electrode (e.g., lower electrode 602). A temperature regulator can be provided in a lower stage 602 (the lower electrode), and a temperature of a substrate 601 placed thereon can be kept at a desired temperature, such as the substrate temperatures noted above. Upper electrode 604 can serve as a gas distribution device, such as a shower plate or showerhead. Precursor gases, oxygen and/or nitrogen reactant gases, and a carrier or inert gas, if any, or the like can be introduced into reaction chamber 603 using one or more of a first gas line 623, a second gas line 624, a third gas line 625, and a fourth gas line 627, from a first source 621, a second source 622, a third source 620, and a fourth source 626, respectively, and through the shower plate 604. Although illustrated with four gas lines, reactor system 600 can include any suitable number of gas lines. By way of examples, the first source 621 can correspond to a precursor gas source, the second source 622 can correspond to a reactive gas source (e.g., one or more of a hydrogen reactant source, an oxygen reactant source and a nitrogen reactant source), the third source 620 can correspond to a purge gas source, and the fourth source 626 can correspond to a metal source or a second reactive gas source.

In reaction chamber 603, a circular duct 613 with an exhaust line 607 can be provided, through which gas in the interior 611 of the reaction chamber 603 can be exhausted. Additionally, a transfer chamber 605, disposed below the reaction chamber 603, can be provided with a seal gas line 629 to introduce seal gas into the interior 611 of the reaction chamber 603 via the interior 616 (transfer zone) of the transfer chamber 605, wherein a separation plate 614 for separating the reaction zone and the transfer zone can be provided (a gate valve through which a substrate is transferred into or from the transfer chamber 605 is omitted from this figure). The transfer chamber can also be provided with an exhaust line 606 coupled to exhaust source 632. In some embodiments, two or more (e.g., all) of the steps of method 100, sequence 200, method 300 and/or sequence 400 can be conducted without exposing the substrate to air or other oxygen-containing atmosphere.

Reactor system 600 can include one or more controller(s) 628 programmed or otherwise configured to cause one or more method steps as described herein to be conducted. Controller(s) 628 are coupled with the various power sources, heating systems, pumps, robotics and gas flow controllers, or valves of the reactor, as will be appreciated by the skilled artisan. By way of example, controller 628 can be configured to control gas flow of a precursor gas, a reactive gas, and carrier gas into at least one of the one or more reaction chambers to form an underlayer or a film on a surface of a substrate. The controller can be similarly configured to perform additional steps as described herein.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

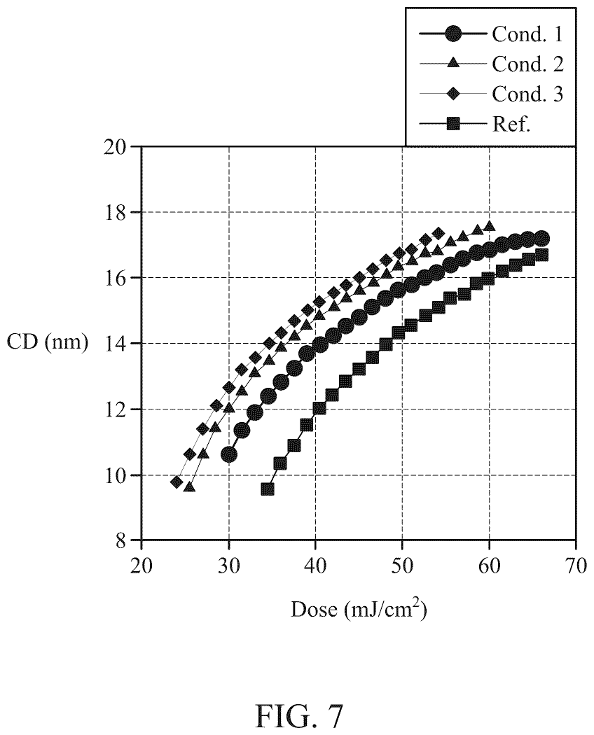

Please refer to FIG. 7, FIG. 7 illustrates properties of the underlayers form by methods according to some embodiments of the present disclosure. FIG. 7 shows four lines, condition 1 (Cond. 1), condition 2 (Cond. 2), condition 3 (Cond. 3) represent the properties of the underlayers formed by the methods of the present disclosure, and the reference (Ref.) shows the properties of an underlayer that is not formed by the methods of the present disclosure.

It can be seen that the doses required for condition 1 (Cond. 1), condition 2 (Cond. 2), condition 3 (Cond. 3) are less than the dose required for the reference (Ref.). Compare the doses required for CD=14 nm, the reference (Ref.) requires approximately 50 mJ/cm2, the condition 1 (Cond. 1) requires approximately 40 mJ/cm², the condition 2 (Cond. 2) requires approximately less than 40 mJ/cm², the condition 3 (Cond. 3) requires approximately much less than 40 mJ/cm².

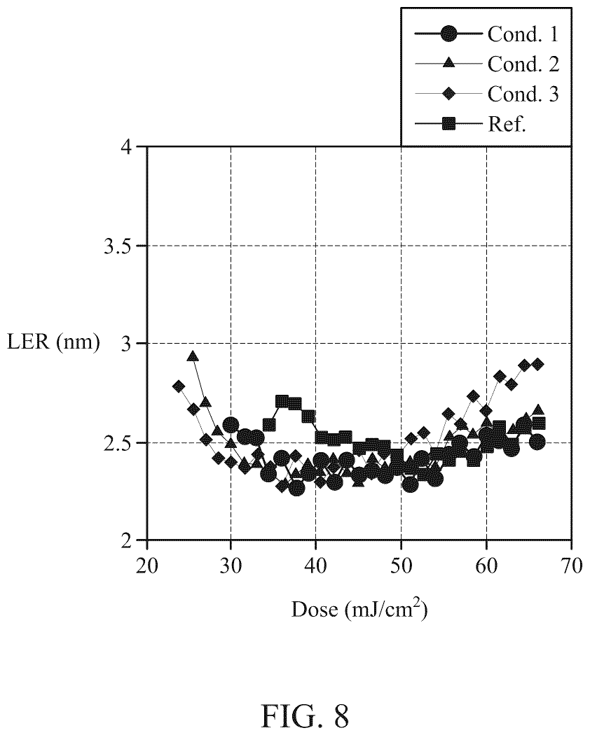

Please refer to FIG. 8, FIG. 8 illustrates properties of the underlayers form by methods according to some embodiments of the present disclosure. FIG. 8 shows four lines, condition 1 (Cond. 1), condition 2 (Cond. 2), condition 3 (Cond. 3) represent the properties of the underlayers formed by the methods of the present disclosure, and the reference (Ref.) shows the properties of an underlayer that is not formed by the methods of the present disclosure.

It can be seen that condition 1 (Cond. 1), condition 2 (Cond. 2), condition 3 (Cond. 3) exhibits lower line edge roughness (LER) value than the reference (Ref.) across the dose range, and condition 1 (Cond. 1), condition 2 (Cond. 2), condition 3 (Cond. 3) show lower line edge roughness (LER) variation.

Although embodiments of the present disclosure and their advantages have been described in detail, it should be understood that various changes, substitutions and alterations may be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, the scope of the present disclosure is defined by the scope of the appended claims. In addition, each scope of the claims is constructed as a separate embodiment, and various combinations of the claims and combinations of embodiments are within the scope of the present disclosure.

What is claimed is:

1. A method for forming an underlayer for lithographic patterning, the method comprising:
providing a substrate into a reaction chamber;
introducing a plasma into the reaction chamber;
introducing a precursor gas into the reaction chamber, wherein the precursor gas comprises at least one carbon-carbon double bond.

2. The method as claimed in claim 1, wherein the precursor gas comprises a cyclic hydrocarbon structure with at least one carbon-carbon double bond in the ring structure.

3. The method as claimed in claim 2, wherein the precursor gas further comprises a least one branched substituent on the cyclic hydrocarbon structure.

4. The method as claimed in claim 3, wherein the branched substituent comprises at least one carbon-carbon double bond.

5. The method as claimed in claim 1, wherein the precursor gas comprises limonene and/or limonene derivatives.

6. The method as claimed in claim 5, wherein the limonene derivatives comprise limonene oxidation/epoxidation derivatives.

7. The method as claimed in claim 6, wherein the limonene oxidation/epoxidation derivatives comprise one or more of: carvone (2-methyl-5-(prop-1-en-2-yl)cyclohex-2-en-1-one, C₁₀H₁₄O), carveol (2-methyl-5-(prop-1-en-2-yl)cyclohex-2-en-1-ol, C₁₀H₁₆O), limonene-1,2-oxide (1,2-epoxy-p-menth-8-ene, C₁₀H₁₆O), limonene dioxide (1,2; 8,9-diepoxy-p-menthane, C₁₀H₁₆O₂), perillyl alcohol (4-(prop-1-en-2-yl)cyclohex-1-en-1-methanol, C₁₀H₁₆O), perillic acid (4-(prop-1-en-2-yl)cyclohex-1-enecarboxylic acid, C₁₀H₁₄O₂), α-terpineol (p-menth-1-en-8-ol, C₁₀H₁₈O), limonene hydroperoxide (4-(prop-1-en-2-yl)cyclohex-1-en-1-yl hydroperoxide, C₁₀H₁₆O₂).

8. The method as claimed in claim 5, wherein the limonene derivatives comprise limonene addition and hydrogenation derivatives.

9. The method as claimed in claim 8, wherein the limonene addition and hydrogenation derivatives comprise one or more of: dihydrolimonene (4-(propan-2-yl)-1-methylcyclohex-1-ene, C₁₀H₁₈), tetrahydrolimonene (p-menthane, C₁₀H₂₀), dihydrocarvone (2-methyl-5-(propan-2-yl)cyclohexan-1-one, C₁₀H₁₈O), dihydrocarveol (2-methyl-5-(propan-2-yl)cyclohexan-1-ol, C₁₀H₂₀O), limonene hydrochloride (4-(propan-2-yl)-1-methylcyclohex-1-yl chloride, C₁₀H₁₇Cl), limonene hydrobromide (4-(propan-2-yl)-1-methylcyclohex-1-yl bromide, C₁₀H₁₇Br), limonene maleic anhydride adduct (2,5-dioxabicyclo[2.2.2]octane-3,6-dione derivative, C₁₄H₂₀O₃), hydrogenated limonene polymer ([C₁₀H₁₆]ₙ).

10. The method as claimed in claim 5, wherein the limonene derivatives comprise limonene esterification or other functionalized derivatives.

11. The method as claimed in claim 10, wherein the limonene esterification or other functionalized derivatives comprise one or more of: carvyl acetate (2-methyl-5-(prop-1-en-2-yl)cyclohex-2-en-1-yl acetate, C₁₂H₂₀O₂), carvyl propionate (2-methyl-5-(prop-1-en-2-yl)cyclohex-2-en-1-yl propanoate, C₁₃H₂₂O₂), dihydrocarvyl acetate (2-methyl-5-(propan-2-yl)cyclohexan-1-yl acetate, C₁₂H₂₂O₂), limonene acrylate (4-(prop-1-en-2-yl)-1-methylcyclohex-1-en-1-yl acrylate, C₁₃H₂₀O₂), limonene methacrylate (4-(prop-1-en-2-yl)-1-methylcyclohex-1-en-1-yl 2-methylprop-2-enoate, C₁₄H₂₂O₂), perillyl acetate (4-(prop-1-en-2-yl)cyclohex-1-en-1-yl acetate, C₁₂H₁₈O₂), epoxidized limonene acrylate (1,2-epoxy-4-(prop-1-en-2-yl)-1-methylcyclohex-1-yl acrylate, ~C₁₃H₂₀O₃), limonene carbonate (4-(prop-1-en-2-yl)-1-methyl-2-oxabicyclo[2.2.2]octan-3-one, C₁₀H₁₆O₃).

12. The method as claimed in claim 1, wherein the underlayer comprises carbon-carbon double bonds.

13. The method as claimed in claim 1, wherein the step of introducing the precursor gas into the reaction chamber is repeated for several times.

14. The method as claimed in claim 1, wherein the precursor gas is pulsing.

15. The method as claimed in claim 1, wherein the plasma is selected from Ar plasma, He plasma, and N₂ plasma.

16. The method as claimed in claim 1, further comprising introducing a reactive gas into the reaction chamber.

17. The method as claimed in claim 16, wherein the reactive gas is selected from H₂, O₂ CO₂, and NH₃, and the reactive gas is continuous.

18. The method as claimed in claim 1, further comprising purging the reaction chamber.

19. The method as claimed in claim 5, wherein the limonene derivatives comprise monoterpenes or other functionalized derivatives.

20. The method as claimed in claim 19, wherein the monoterpenes or other functionalized derivatives comprise one or more of: pinene (C₁₀H₁₆), carene (C₁₀H₁₆), camphene (C₁₀H₁₆), terpinene (C₁₀H₁₆), phellandrene (C₁₀H₁₆), sabinene (C₁₀H₁₆), terpinolene (C₁₀H₁₆).
